(19) United States
(12) Patent Application Publication
(10) Pub. No.: US 2007/0266946 A1
(43) Pub. Date: Nov. 22, 2007

(54) Semiconductor device manufacturing apparatus and method of using the same

(76) Inventor: Byung-Chul Choi, Hwaseong-si (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/593,493

(22) Filed: Nov. 7, 2006

(30) Foreign Application Priority Data
May 22, 2006 (KR) 2006-0045559

(51) Int. Cl. H05H 1/24; C23C 16/00

(52) U.S. Cl. 118/723 ER; 118/715; 118/723 E; 427/569

(57) ABSTRACT

A semiconductor device manufacturing apparatus and a method for use in the manufacturing of such devices minimize the amount of particles which accumulate in the process chamber of the apparatus and clean the interior of the process chamber with a high degree of effectiveness. The semiconductor device manufacturing apparatus has a showerhead located at an upper portion of the process chamber, a plate-like gas diffuser disposed in the showerhead, and both a fluid supply line and a plasma waveguide connected to the showerhead. After a substrate is processed in the process chamber using process gas delivered to the showerhead through the fluid supply line, plasma is supplied into the upper portion of the process chamber from a remote plasma reactor via the plasma waveguide.

### BACKGROUND OF THE INVENTION

1. Field of the Invention

The present invention relates to apparatus for processing substrates such as semiconductor wafers. More particularly, the present invention relates to the cleaning of a process chamber of a semiconductor device manufacturing apparatus or the like using plasma.

2. Description of the Related Art

Generally, semiconductor devices are fabricated by selectively and repetitively performing a number of unit processes on a substrate referred to as a wafer. These processes typically include an ion implantation process of implanting impurities into the substrate, a thin layer deposition process of forming a conductive layer of material on the substrate, an etching process of etching the conductive layer into a desired geometric pattern, a deposition process of forming an interlayer insulating layer on the patterned conductive layer, and a planarization process of planarizing the interlayer insulating layer to remove steps in the layer. Each or several of these unit processes is carried out on the substrate in a process chamber. Therefore, many particles which could potentially contaminate a semiconductor substrate are inevitably generated in the process chambers of semiconductor device manufacturing apparatus. Accordingly, a process chamber is cleaned to remove particles from inside the chamber after a unit process has been carried out in the chamber.

Among such apparatus, a thin layer deposition apparatus forms various layers, e.g. a conductive layer, an insulating layer, on a wafer using process gases which are fed into the process chamber of the apparatus. Hence, residual process gas, by-products of the deposition process, etc. can contaminate the process apparatus. Specifically, particles can accumulate on an inner wall of the process chamber as well as on other internal parts of the deposition apparatus such as on a heater and a chuck disposed within the process chamber. Particles can also accumulate in a vacuum line of a vacuum system comprising a turbo pump, for example, connected to the process chamber.

Therefore, residual process gas is pumped from the process chamber using the vacuum system (e.g., a turbo pump) after a thin layer deposition process has been completed. Also, the inside of the process chamber is cleaned by plasma while the interior of the process chamber is being purged of the residual gas. Thus, the gas and particles are removed from the chamber.

One method of cleaning a process chamber using plasma is the direct plasma clean (DPC) method. The DPC method cleans the inside of the process chamber by directly injecting plasma source gas into the process chamber, and then directly forming the plasma in the process chamber by exciting the plasma source gas. However, in the DPC method, the plasma generated in the process chamber can damage the process apparatus. Furthermore, the DPC method requires a relatively long amount of time and thus causes a significant downturn in the productivity of the semiconductor device manufacturing process.

Therefore, a remote plasma clean (RPC) method has been developed as an alternative to the DPC. The RPC method cleans the inside of the process chamber by generating plasma in advance outside the process chamber using a reactor, and then injecting the plasma into the process chamber through a waveguide. In the RPC method, the plasma does damage the process apparatus because it is generated using a reactor located outside the process chamber. Furthermore, it takes a comparatively short amount of time to clean the interior of the process chamber using an RPC method because the plasma used to clean the apparatus is generated before the end of the deposition process.

However, even the RPC method has limitations in some deposition apparatus. For instance, ATTO deposition equipment, which forms a plasma-enhanced tetraethoxysilane (PETEOS) insulating layer, on a semiconductor substrate, includes a waveguide connected to the side of the process chamber. Hence, the waveguide and the region of the process chamber adjacent the waveguide can be satisfactorily cleaned using an RPC method. On the other hand, regions of the process chamber remote from the location at which the waveguide is connected to the process chamber can not be cleaned satisfactorily. In particular, a slit valve disposed across the process chamber from the waveguide can not be cleaned well by plasma directed into the process chamber through the waveguide.

Accordingly, particles can remain in the process chamber after the cleaning process. The particles can attain a size of several hundred times that of fine dust. Once the particles reach this size, the particles may fall onto a wafer which has just been placed into the process chamber. Particles this size have a fatal affect on the manufactured semiconductor device. The time taken to clean the inside of the process chamber could be increased in an attempt to ensure that no such particles existed in any portion of the process chamber. However, the amount of time required would so adversely affect the productivity of the semiconductor device manufacturing process as to make it unfeasible.

Furthermore, ATTO equipment includes a shower head for injecting process gas uniformly into the process chamber, a baffle for diffusing the process gas within the showerhead, and a triangular pole coupling the baffle to a lid of the process chamber. However, heat can radiate rapidly from the triangular pole because it extends through free space between lid of the process chamber and the baffle. Thus, the baffle connected to the triangular pole cools as the triangular pole cools down. Moreover, the baffle deflects the process gas and hence, the baffle slows the flow of the process gas as the process gas flows toward the outlet of the showerhead. Therefore, process gas condenses on the baffle and as a result, particles are formed on the baffle. These particles can be injected into the process chamber through the shower head together with process gas. As a result, the inside of the process chamber is contaminated by the particles, the quality of the thin layer formed on the wafer is lowered, and the semiconductor devices produced using the thin film deposition apparatus have low degrees of reliability.

Furthermore, a relatively complex RPC method must be employed in an attempt to eliminate particles generated as the result of the cooling of the process gas on the baffle. In some cases, contaminated portions of the equipment must be replaced which gives rise to increased time and costs in connection with the overall process of fabricating the semiconductor devices.

### SUMMARY OF THE INVENTION

Therefore, an object of the present invention is to provide a substrate processing apparatus, and a substrate processing method, by which the entire inside of the process chamber can be cleaned.

It is another object of the present invention to provide a substrate processing apparatus, and a substrate processing method, by which the inside of a process chamber can be cleaned in a short amount of time.

It is another object of the present invention to provide a substrate processing apparatus having a showerhead and a gas diffuser but in which a significant amount of particles is not generated in the showerhead.

It is another object of the present invention to provide a substrate processing apparatus, and a substrate processing method, by which substrates being processed are prevented from being contaminated and by which components of the processing equipment are prevented from being ruined by particles.

According to one aspect of the present invention, there is provided a semiconductor device manufacturing apparatus which includes a process chamber, a process fluid supply unit connected to an upper portion of the process chamber, and a remote plasma generator also connected to the upper portion of the process chamber. The process fluid supply unit includes a fluid supply line, and a showerhead disposed at an upper portion of the process chamber. The fluid supply line is connected to the showerhead. Thus, the showerhead injects fluid fed through the fluid supply line into the process chamber. The plasma supply unit includes a remote plasma reactor disposed outside of the process chamber, and a plasma supply line connected to the remote plasma reactor and to the process chamber. The plasma supply line has an open end disposed at the upper portion of the process chamber such that plasma generated by the remote plasma reactor is injected downward into the process chamber from the upper portion of the process chamber.

According to another aspect of the present invention, the process fluid supply unit also includes a process gas supply source having at least one source of gas used in the processing of a substrate within the process chamber. Also, the processing apparatus includes an upper electrode, and a lower electrode on which a substrate to be processed is seated. Radio frequency power supplied to the electrodes to excite gas within the process chamber and thereby convert the gas to plasma.

According to still another aspect of the present invention, the process fluid supply unit further includes a diffuser disposed in the showerhead to diffuse gas fed through the process fluid supply line throughout the showerhead before the gas is injected by the showerhead into the process chamber. The diffuser consists of a plate having passageways extending straight therethrough. Therefore, the gas is injected rapidly into the process chamber and this, does not have time to cool and condense on the diffuser or showerhead.

According to yet another aspect of the present invention, there is provided a substrate processing method in which a substrate is set in a lower portion of a process chamber, a processing medium comprising gas is subsequently injected into the process chamber from an upper portion of the process chamber and the substrate is processed using the processing medium, and subsequently the interior of the process chamber is cleaned by injecting cleaning plasma generated by a remote plasma generator into the process chamber from the upper portion of the process chamber.

### BRIEF DESCRIPTION OF THE DRAWINGS

The above and other objects, features and advantages of the present invention will become more apparent to those of ordinary skill in the art by referring to the following detailed description of the preferred embodiments thereof made with reference to the attached drawings in which:

FIG. 1 is a perspective view of a semiconductor device manufacturing apparatus according to the present invention;

FIG. 2 illustrates a sectional view of the semiconductor device manufacturing apparatus of FIG. 1; and

FIG. 3 is a flowchart of a thin layer deposition process and a plasma cleaning process performed using a semiconductor device manufacturing apparatus according to the present invention.

### DETAILED DESCRITPION OF THE PREFERRED EMBODIMENTS

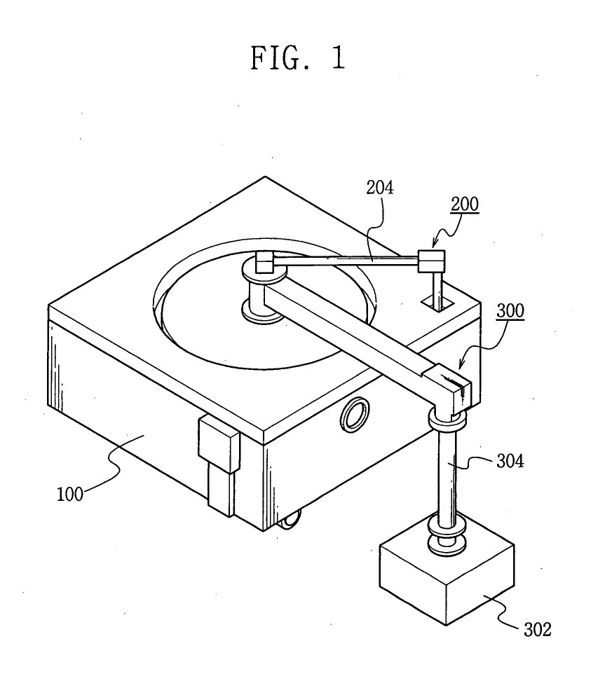

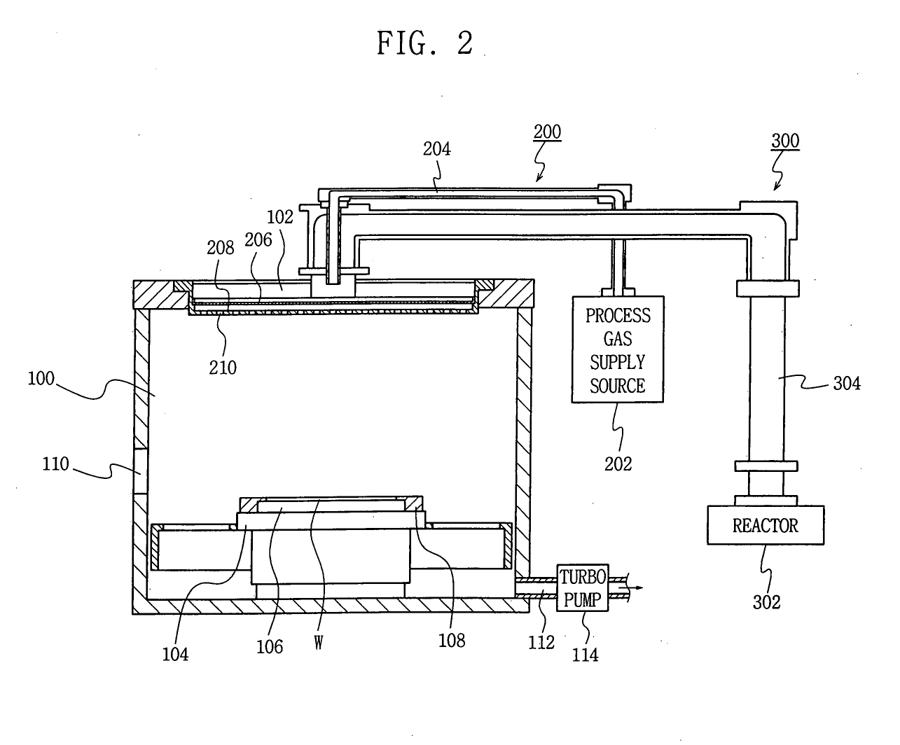

FIGS. 1 and 2 illustrate a thin layer deposition apparatus as one example of a semiconductor device manufacturing apparatus according to the present invention. More specifically, FIGS. 1 and 2 illustrate a plasma-enhanced chemical vapor deposition (CVD) apparatus for forming a plasma-enhanced tetraethoxysilane (PETEOS) insulating layer on a substrate. However, although the present invention will be described in the context of a plasma-enhanced chemical vapor deposition (CVD) apparatus, the present invention may be applied to other processing apparatus. For instance, the present invention can be applied to etching and diffusion apparatus.

Referring first to FIG. 1, the plasma-enhanced chemical vapor deposition (CVD) apparatus has a process chamber 100 in which a process of forming a PETEOS insulating layer on a substrate is performed. A process gas supply unit 200 is coupled to a lid of the process chamber 100. The process gas supply unit 200 supplies the process gas, used to form the PETEOS insulating layer, to the process chamber 100 through a gas supply line 204. The plasma-enhanced chemical vapor deposition (CVD) apparatus also has a plasma supply unit 300, which supplies plasma for cleaning the inside of the process chamber 100. The plasma supply unit 300 comprises a remote reactor 302 for generating plasma outside the process chamber, and a plasma supply line, i.e., a waveguide 304, for supplying the plasma generated by the reactor 302 into the process chamber 100.

Referring to FIG. 2, an upper electrode 102 is disposed at an upper portion of the process chamber 100. An RF power of about 300 watts supplied to the upper electrode 102 by an RF power source. The RF power excites the process gas supplied through the gas supply line 204 of the process gas supply unit 200, thereby converting the process gas in the process chamber 100 to the plasma for forming the PETEOS insulating layer on a wafer W.

A lower electrode 104 is disposed at a lower portion of the process chamber 100. An RF power of about 600 watts is supplied by an RF power supply to the lower electrode 104 for use in generating the plasma together with the RF power supplied to the upper electrode 102. An electrostatic chuck 106 on which the wafer W is seated is disposed on the lower electrode 104. A clamp ring 108 extends around the electrostatic chuck 106. The clamp ring 108 protrudes above the outer periphery of the electrostatic chuck 106 to surround the wafer W seated on the electrostatic chuck 106. The clamp ring 108 thus fixes the wafer W in position on the electrostatic chuck 106. The process chamber 100 also has a wafer input port 110 through which wafer W can be loaded into the process chamber 100 and set on the electrostatic chuck 106. The wafer input port 110 is located at one side of the process chamber 100.

In addition to the gas supply line 204, the process gas supply unit 200 includes a process gas supply source 202 comprising sources of the process gas (e.g., sources of oxygen and helium for forming the plasma, and a source of TEOS gas) required for forming a PETEOS insulating layer on the wafer, a process gas diffuser 206, and a showerhead 208 to which the gas supply line 204 is connected. The process gas diffuser 206 is mounted in the showerhead 208 and consists of a plate having minute linear passageways extending completely therethrough (from one side to the other). The shower head 208 has an injection plate defining a plurality of holes 210 through which the process gas is injected into the process chamber 100. The process gas diffuser 206 is the only element interposed between the end of the process gas supply line 204 and the injection plate of the showerhead 208. Therefore, the process gas flowing through the process gas supply line 204 is supplied into the process chamber 100 uniformly by the process gas diffuser 206 and the shower head 208. Although not illustrated in the drawings, a flow controller is provided in the process gas supply line 204 for controlling the rate at which fluid flows through the process gas supply line 204.

According to the present invention as described above, the process gas flowing through the process gas supply line 204 flows in a straight path through the plate-like process gas diffuser 206 and the showerhead 208 at a rapid speed whereupon the process gas is directly injected into the process chamber 100. Thus, particles in the process gas will not accumulate on the gas diffuser, unlike the case of the baffle employed in the prior art. Accordingly, the PETEOS insulating layer formed on the wafer will be of a high quality and so, the resulting semiconductor device can be highly reliable. Furthermore, the process chamber will not be contaminated by particles coming from the showerhead 208. Therefore, the process chamber 100 can be subsequently cleaned quite effectively with plasma so that the useful life of the apparatus is prolonged which, in turn, helps keep manufacturing expenses to a minimum.

Referring again to FIG. 2, the plasma-enhanced chemical vapor deposition (CVD) apparatus also includes a vacuum system comprising an exhaust line 112 disposed outside of and connected to the process chamber 100, and a turbo pump 114 connected to the exhaust line. The inside of the process chamber 100 is evacuated using the turbo pump 114 to maintain the inside of the process chamber 100 at a pressure suitable for the deposition process of forming the PETEOS insulating layer. Specifically, the pressure of the process chamber 100 is increased as the process gas for forming the PETEOS insulating layer is fed into the process chamber 100. At this time, the turbo pump 114 is operated to adjust regulate the pressure and maintain he pressure at a level suitable for the deposition process. In addition, the turbo pump 114 is used to exhaust the process chamber 100 of non-reacted gas that remains in the process chamber 100 after the deposition process has been completed and of by-products of the deposition process.

The plasma supply unit 300 and, in particular, the plasma supply line 304 (e.g., a waveguide) for supplying the plasma into the process chamber 100, is connected to the upper portion of the process chamber 100, unlike in the conventional semiconductor device manufacturing apparatus. Specifically, the respective ends of the waveguide 304 and gas supply line 204 are disposed concentrically at the top of the process chamber 100. In particular, an end of the waveguide 304 extends around the gas supply line 204 of the process gas supply unit 200 and opens into the showerhead 208 at the upper portion of the process chamber. Thus, the plasma generated by the reactor 302 is uniformly injected over the entire processing region within the process chamber, so that the process chamber can be cleaned throughout the entirety thereof. In addition, the process gas diffuser 206 and the shower head 208 of the process gas supply unit 200 are cleaned because the plasma flowing from the plasma supply line 304 is injected into the process chamber 100 through the process gas diffuser 206 and the shower head 208.

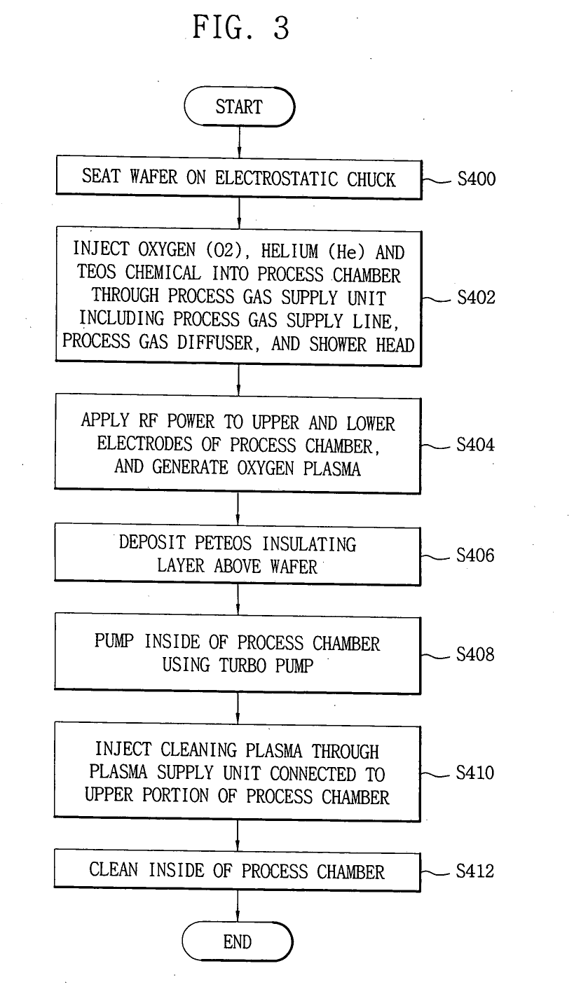

Now, a deposition process of forming a PETEOS insulating layer and a process of cleaning the process chamber in which the deposition process has been completed using the semiconductor device manufacturing apparatus according to the present invention will be described with reference to FIGS. 1 and 2 and the flowchart of FIG. 3.

First, a wafer is seated on the electrostatic chuck 106 in the process chamber 100 (S400). Then, oxygen (O₂), helium (He), and TEOS gas are injected into the process chamber 100 while a pressure of about 2.5 Torr and a temperature of about 350° C. are maintained within the process chamber 100 (S402). More specifically, the O₂ and the He are injected at about 8000 SCCM (standard cubic centimeters per minute) and about 1000 SCCM, respectively into the upper portion of the process chamber 100 through the gas diffuser 206 and the showerhead 208. The TEOS gas is derived from liquid tetraethoxysilane (Si(OC₂H₅)₄; TEOS) in the process gas supply source 202, injected at about 350 SCCM into the upper portion of the process chamber 100 through the gas diffuser 206 and the showerhead 208.

At the same time, RF power of 300 watts and 600 watts are respectively supplied to the upper and lower electrodes 102 and 104 of the process chamber 100. As a result, an O₂ plasma atmosphere is formed inside the process chamber 100 (S404), and a PETEOS insulating (oxide) layer is formed on the wafer to a desired thickness (S406).

Subsequently, the deposition apparatus is cleaned (S412). First, the inside of the process chamber is evacuated by the turbo pump (S408). As a result, various particles generated during the deposition process are discharged from the process chamber 100 together with residual process gas. Subsequently, fluorine (F) plasma already generated by the reactor 302 of the plasma supply unit 300 is injected into the upper portion of the process chamber through the plasma supply line 304, gas diffuser 206 and showerhead 208 (S410). In this manner, the fluorine plasma is uniformly injected over the entire processing space within the process chamber 100 starting with the upper region of the process chamber 100. Therefore, the entire processing region of the process chamber 100 can be cleaned. Furthermore, the plasma cleans the process gas diffuser 206 and the shower head 208 of the process gas supply unit 200.

As described above, the process gas flowing through the process gas supply line 204 is rapidly injected into the process chamber through the plate-like process gas diffuser 206 and the shower head 208. As a result, the process gas is not allowed to cool between the time it issues from the end of the gas supply line 204 and the time it is injected into the chamber by the showerhead 208. Thus, only a minimal amount of particles may accumulate on the showerhead 208, a high quality thin layer can be formed on the wafer and the contamination inside the process chamber is minimized. Furthermore, the plasma for cleaning the inside of the process chamber is supplied inot the process chamber from the upper portion of the process chamber. Thus, a wide region of the process chamber can be cleaned effectively.

Finally, although the present invention has been described in connection with the preferred embodiments thereof, it is to be understood that the scope of the present invention is not so limited. On the contrary, various modifications of and changes to the preferred embodiments will be apparent to those of ordinary skill in the art. Thus, changes to and modifications of the preferred embodiments may fall within the true spirit and scope of the invention as defined by the appended claims.

What is claimed is:

1. A manufacturing apparatus for processing substrates, comprising:
a process chamber;
a process fluid supply unit including a fluid supply line, and a showerhead disposed at an upper portion of the process chamber and to which the fluid supply line is connected whereby the showerhead injects fluid fed through the fluid supply line into the process chamber; and
a plasma supply unit including a remote plasma reactor disposed outside of the process chamber, and a plasma supply line connected to the remote plasma reactor and to the process chamber, the plasma supply line having an open end disposed at the upper portion of the process chamber such that plasma generated by the remote plasma reactor is injected downward into the process chamber from the upper portion of the process chamber.

2. The manufacturing apparatus according to claim 1, wherein the process fluid supply unit further includes a diffuser disposed in the showerhead to diffuse gas fed through the process fluid supply line throughout the showerhead before the gas is injected by the showerhead into the process chamber.

3. The manufacturing apparatus according to claim 2, wherein the diffuser consists of a plate having passageways extending straight therethrough.

4. The manufacturing apparatus according to claim 3, wherein the process chamber comprises a lid forming the top thereof, and the showerhead of the process supply unit is mounted to the lid of the process chamber.

5. The manufacturing apparatus according to claim 4, wherein the end of the plasma supply line of the plasma supply unit is attached to the lid of the process chamber along with the showerhead.

6. The manufacturing apparatus according to claim 5, wherein the plasma supply line is a waveguide.

7. A manufacturing apparatus for processing substrates, comprising:
a process chamber;
a process fluid supply unit including a process gas supply source having at least one source of gas used in the processing of a substrate within the process chamber, a fluid supply line, and a showerhead disposed at an upper portion of the process chamber and to which the fluid supply line is connected whereby the showerhead injects fluid fed through the fluid supply line from the process gas supply source into the process chamber; and
a plasma supply unit including a remote plasma reactor disposed outside of the process chamber, and a plasma supply line connected to the remote plasma reactor and to the process chamber, the plasma supply line having an open end disposed at the upper portion of the process chamber such that plasma generated by the remote plasma reactor is injected downward into the process chamber from the upper portion of the process chamber.

8. The manufacturing apparatus according to claim 7, wherein the process chamber comprises a lid forming the top thereof, and the showerhead of the process supply unit is mounted to the lid of the process chamber.

9. The manufacturing apparatus according to claim 8, wherein the end of the plasma supply line of the plasma supply unit is attached to the lid of the process chamber along with the showerhead.

10. The manufacturing apparatus according to claim 9, wherein the process fluid supply unit further includes a diffuser disposed in the showerhead to diffuse gas fed through the process fluid supply line throughout the showerhead before the gas is injected by the showerhead into the process chamber.

11. The manufacturing apparatus according to claim 10, wherein the diffuser consists of a plate having passageways extending straight therethrough.

12. The manufacturing apparatus according to claim 11, wherein the plasma supply line is a waveguide.

13. The manufacturing apparatus according to claim 7, further comprising:
an upper electrode disposed in the process chamber;
a lower electrode disposed below the upper electrode in the process chamber; and
RF power supplies connected to the electrodes, respectively.

14. The manufacturing apparatus according to claim 11, wherein the process gas supply source includes a source of TEOS.

15. A substrate processing method comprising:
supporting a substrate in a lower portion of a process chamber;
subsequently injecting a processing medium comprising gas into the process chamber from an upper portion of the process chamber, and processing the substrate using the processing medium;
subsequently cleaning the interior of the process chamber by generating a cleaning plasma outside the process chamber, and injecting the cleaning plasma into the process chamber from the upper portion of the process chamber.

16. The method according to claim 16, wherein the processing of the substrate using the processing medium comprises exciting the process gas within the process chamber to convert the process gas into a plasma within the process chamber.

17. The method according to claim 15, wherein the injecting of the processing medium into the process chamber comprises delivering the processing medium into a showerhead disposed at the upper portion of the process chamber, and the injecting of the cleaning plasma into the process chamber also comprises delivering the cleaning plasma into the showerhead, whereby the cleaning plasma cleans the showerhead in addition to the interior of the process chamber.

18. The method according to claim 17, further comprising diffusing the processing medium in the showerhead by delivering the processing medium onto a diffuser consisting of a plate disposed within the showerhead, the plate having passageways extending straight therethrough, and wherein the cleaning plasma is also delivered to the diffuser, whereby the cleaning plasma cleans the diffuser in addition to the showerhead and the interior of the process chamber.

19. The method according to claim 16, wherein the injecting of the processing medium into the process chamber comprises delivering the processing medium into a showerhead disposed at the upper portion of the process chamber, and the injecting of the cleaning plasma into the process chamber also comprises delivering the cleaning plasma into the showerhead, whereby the cleaning plasma cleans the showerhead in addition to the interior of the process chamber.

20. The method according to claim 15, wherein the injecting of the processing medium into the process chamber comprises delivering TEOS to the showerhead.
